(19) United States
(12) Patent Application Publication
(10) Pub. No.: US 2007/0247179 A1
(43) Pub. Date: Oct. 25, 2007

(54) Surface mount component RF test fixture

(75) Inventors: James Paul Kingston, Pepperell, MA (US); Stanley Vincent Paquette, Dracut, MA (US); Paul Arthur Cushion, Dunstable, MA (US)

Correspondence Address: Brian C. Oakes;Tyco Electronics Corporation, Suite 140, 4550 New Linden Hill Road, Wilmington, DE, 19808-2952, US

(73) Assignee: M/A Com, Inc.

(21) Appl. No.: 11/411,387

(22) Filed: Apr. 25, 2006

(51) Int. Cl. G01R 31/02

(52) U.S. Cl. 324/755

(57) ABSTRACT

A surface mount component RF test fixture and method for testing a surface mount device are provided. The test fixture includes a testing board configured to receive a surface mount device and at least one testing interface configured to connect the testing board with the surface mount device. The at least one testing interface also configured to compensate for planar deviations of the connection between the surface mount device and the at least one testing interface.

### BACKGROUND OF THE INVENTION

This invention relates generally to test fixtures, and more particularly, to a test fixture for testing surface mount components.

Test fixtures provide an interface between the test instrumentation, the device to be tested and the person performing the test. Test fixtures are typically designed to test a particular device or line of devices. The test fixtures are usually placed on a test platform using an electromechanical interface.

Test fixtures may be used to test, for example, different electronic, radio frequency (RF) and/or microwave devices. The devices to be tested may include numerous connectors or ports that are interfaced using the test fixture. For example, when testing surface mount components, such as surface mount ferrite devices used for communication, the test fixture allows connection to each of the ports for testing. However, known test fixtures do not allow for variations in the planar relationship between the base of the device, for example, the base of a surface mount ferrite device (ground) and each of the rigid RF ports.

Thus, because these known test fixtures do not compensate for planar deviations, good contact may be difficult to obtain. This adds time and complexity to the testing process, for example, with a user having to try to obtain a better contact. Further, the planar deviations may result in reduced signal integrity during testing, which signal quality may be less than satisfactory and not within testing tolerances or guidelines. Thus, devices may not be properly tested or might improperly fail.

### BRIEF DESCRIPTION OF THE INVENTION

In one exemplary embodiment, a test fixture is provided that includes a testing board configured to receive a surface mount device and at least one testing interface configured to connect the testing board with the surface mount device. The at least one testing interface also configured to compensate for planar deviations of the connection between the surface mount device and the at least one testing interface.

In another exemplary embodiment, a surface mount device test fixture is provided that includes a testing board configured to support a ferrite type surface mount device and a plurality of testing interfaces configured to connect the ferrite type surface mount device to a ground plane of the testing board. The plurality of testing interfaces are configured to move perpendicularly relative to the testing board. The surface mount device test fixture also includes a resilient grounding member supporting each of the plurality of testing interfaces.

In yet another exemplary embodiment, a method for testing a surface mount device is provided. The method includes configuring a testing board to receive a surface mount device and movingly engaging at least one testing interface with the testing board. The at least one testing interface configured to connect the surface mount device to the testing board.

### BRIEF DESCRIPTION OF THE DRAWINGS

FIG. 1 is a top perspective view of a test fixture constructed in accordance with an embodiment of the invention.

FIG. 2 is a top perspective view of the test fixture of FIG. 1 showing an exploded view of one testing interface and a phantom view of another testing interface.

FIG. 3 is a top perspective view of a test fixture constructed in accordance with another embodiment of the invention.

FIG. 4 is a perspective view of an interface portion of a testing interface constructed in accordance with an embodiment of the invention.

FIGS. 5A and 5B are elevation views of the interface portion of FIG. 4 connected to a base portion forming the testing interface and illustrating flexible operation.

FIG. 6 is a top perspective view of a test fixture constructed in accordance with an embodiment of the invention having a device secured thereto in one configuration using alignment members.

FIG. 7 is a top perspective view of a test fixture constructed in accordance with an embodiment of the invention having a device secured thereto in another configuration using alignment members.

### DETAILED DESCRIPTION OF THE INVENTION

Various embodiments of the invention provide a test fixture for testing surface mount devices, such as surface mount microwave devices. For example, the various embodiments provide for RF testing of surface mount components including surface mount ferrite devices. The test fixtures accommodate planar deviations between the RF ground and the various signal ports of the device.

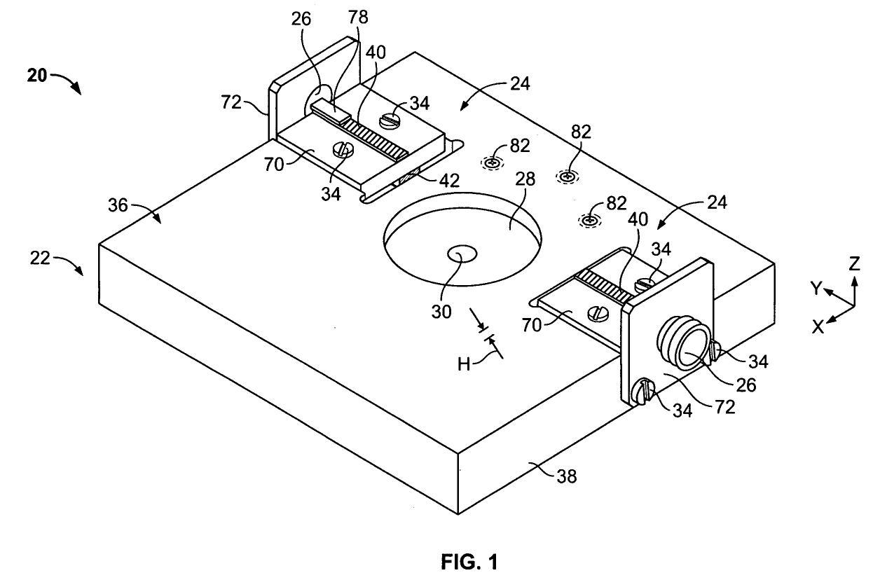

Specifically, as shown in FIG. 1, a test fixture 20 constructed in accordance with various embodiments of the invention generally includes a testing board 22 having a plurality of testing interfaces. The testing board 22 may be sized and shaped in different configurations, for example, based on the devices to be tested. The testing board 22 may be constructed of (i) a conductive material, for example, brass, copper, aluminum, steel, etc. or (ii) a non-conductive material, for example, plastic, with an electrically conductive plating such as silver, nickel, gold, etc. The testing board 22 defines a rigid ground plane and the plurality of testing interfaces 24 include connection ports 26 configured to be connected to external testing equipment (not shown). The testing interfaces 24 are connected to the testing board 22 with a plurality of fasteners, for example, screws 34, which in one embodiment includes connection both at a top surface 36 of the testing board 22 with shouldered screws and a side surface 38 of the testing board 22 with standard screws (e.g., pan head screws). Each testing interface 24 includes a connection strip 40 (e.g., a copper strip) providing electrical connection between the connection port 26 and the device to be tested (e.g., the signal ports of the device to be tested). Further, each testing interface 24 is engaged with a top of a resilient grounding member 42 (e.g., abuttingly engaged) and configured to allow upward and downward (e.g., horizontal or perpendicular) movement of the testing interface 24 relative to the testing board 22, which movement may be allowed in part due to the configuration of the fasteners. For example, movement is provided in the z-direction and resisted or prevented in the x-direction and y-direction, such that semi-floating test points are defined. In an exemplary embodiment, the resilient grounding member 42 is constructed of a foam rubber type material that may be partially or completely surrounded by a conductive material or layer (e.g., a conductive netting).

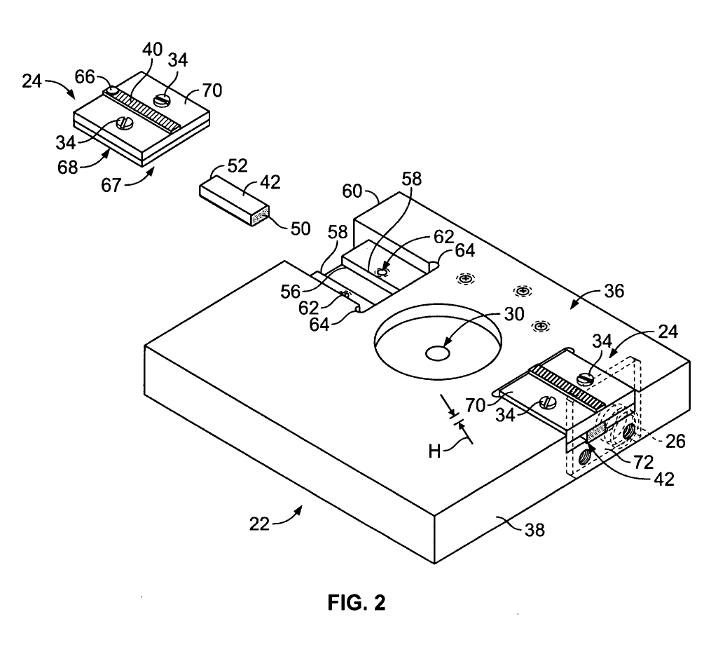

More particularly, as shown in FIG. 2, the resilient grounding member 42 may be configured as a low to moderate durometer resilient grounding pad, for example, a foam rubber wrapped in a conductive outer surface, for example, a soft foam wrapped in an electrically conductive netting. For example, the material may measure 1 lbf per linear inch for 35% deflection. Additionally, grounding alternatively may be provided using a flexible strap of electrically conductive material with spring-like characteristics as are known for use in shielding electronic devices, for example, a beryllium copper spring strap. First and second sides 50 and 52 of the resilient grounding member 42, which may be opposite ends, may be provided (e.g., coated) with copper, with one of the sides, for example, the first side 50 having an etched pattern. As shown in FIG. 2, a recessed portion, and more particularly, a slot 56 defining an indented portion or channel, is provided and configured to receive therein the resilient grounding member 42. It should be noted that in an exemplary embodiment the height of the resilient grounding member 42 is greater than the depth of the slot 56, such that the resilient grounding member 42 extends beyond upper edges 58 of the slot 56.

Further, another recessed portion, and more particularly, a cutout region 60 above the slot 56 is configured to receive therein the testing interface 24. Openings 62, for example, bores may be provided for receiving therein the screws 34 of the testing interface 24. The openings 62 may include complimentary features or portions (e.g., threading) that engage the screws 34. The cutout region 60 also may include rounded comers 64, which may be included, for example, to provide a clearance for machining tools during manufacture of the testing board 22. For example, the rounded comers 64 may provide a clearance region for sharp comers of a strip-line board.

The testing interface 24 optionally may include a pad 66 (e.g., solder pad or Duroid type pad), for example, at an out contact area (closer to the device to be tested) of the testing interface 24. Further, the testing interface 66 optionally may include an electrically conductive layer 68 provided (e.g., laminated) on a bottom surface 67 of the testing interface 24 and configured in an exemplary embodiment to provide grounding.

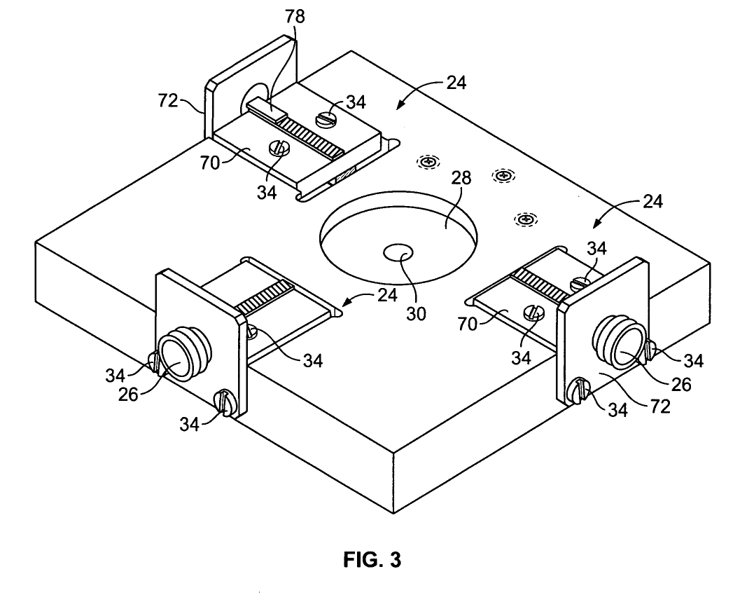

It should be noted that although the test fixture 20 is shown having only two testing interfaces 24, additional testing interfaces 24 may be provided, for example, to test devices having more than two connectors or I/O ports (e.g., signal ports). For example, as shown in FIG. 3, three testing interfaces 24 may be provided to test, for example, a three-port device. It also should be noted that a base portion 70 of each of the testing interfaces 24 is configured to extend slightly higher or above the ground plane defined by the testing board 22 (e.g., higher than the top surface 36 of the testing board 22), which is indicated by H in FIGS. 1 and 2. The height may be based on, for example, the co-planarity tolerance of the device to be tested. For example, if the co-planarity of the contact points of the device under test relative to a grounding base for the device are allowed to deviate a nominal amount, for example, by 0.005 inches, in the upward direction, then the height H must be greater than this distance, such as, greater by a few thousands of an inch to ensure physical contact between the contacts and the conductive connection strip 40.

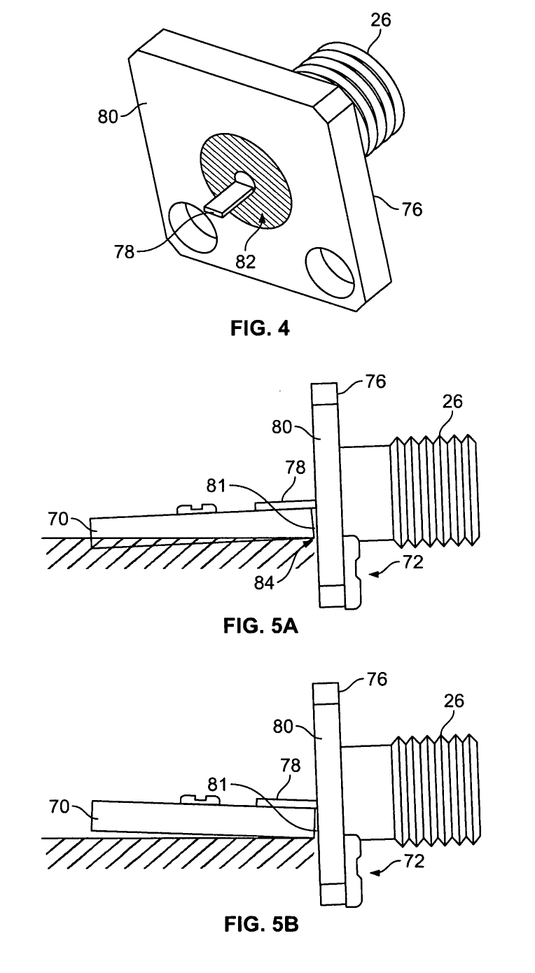

The testing interfaces 24, as shown in FIGS. 1 through 3 generally include the base portion 70 and an interface portion 72 that includes the connection port 26, which may be permanently or removably attached thereto. Removable attachment allows attachment of connection ports 26 having different configurations and/or sizes. The interface portion 72 is generally perpendicular to the base portion 70. The base portion 70 and interface portion 72 may be formed as a single unitary piece or may be constructed of two separate pieces. For example, as shown in FIG. 4, a separate interface portion 72 may include the connection port 26 on a front surface 76 and an extension 78 (e.g., electrical tab) on a back surface 80 extending generally from the center of the back surface 80. Essentially, the extension 78 extends from a center conductor 82 and is configured to allow flexing relative to the back surface 80. The extension 78, for example, may be constructed of a steel or beryllium copper material to allow a number of flexing cycles (e.g., numerous upward and downward flexing cycles).

The extension 78 is connected to the connection strip 40 (shown in FIG. 1) of the base portion 70, for example, by soldering. As shown in FIGS. 5A and 5B, a gap 84 is provided between the back surface 80 of the base portion 70 and a side surface 81 of the interface portion 72 when the extension 78 is connected to the connection strip 40. The gap 84 may be varied, for example, to increase or decrease the amount of flex to the extension 78 when used for testing different devices (e.g., devices having one or more ports that are not coplanar with the base of the device).

In operation, as shown in FIGS. 5A and 5B, the extension 78 is configured to allow flexing movement. In particular, as shown in FIG. 5A, the extension 78 allows negative or downward flexing of the base portion 70 relative to the interface portion 72. As shown in FIG. 5B, the extension 78 also allows positive or upward flexing of the base portion 70 relative to the interface portion 72. This flexing operation allows the base portion 70 to move up and down (e.g., perpendicular to the testing board 22) with the resilient grounding member 42 to allow for an amount of deviation from coplanar that may occur when testing a device using the testing fixture 20.

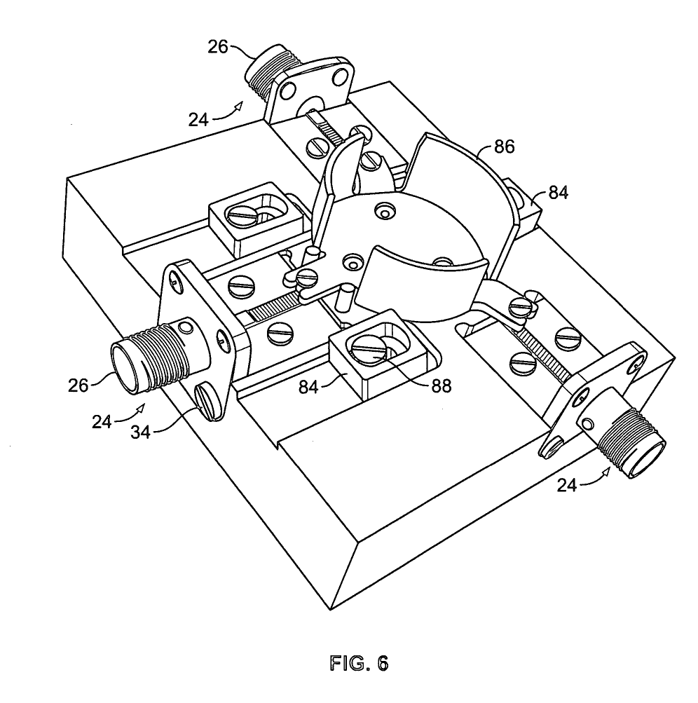

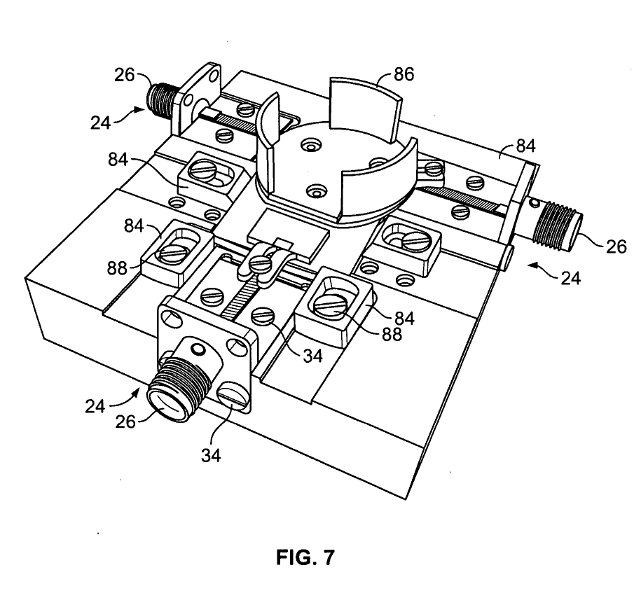

Referring again to FIGS. 1 through 3, the testing board 22 may include portions or members to, for example, maintain the position of a device to be tested. For example, the testing board 22 also may include a mounting portion 28 for receiving and maintaining therein at least a portion of a device to be tested. In one embodiment, the mounting portion 28 includes a recessed area having a vacuum port 30 that may be connected to, for example, an external vacuum source (not shown) and configured to maintain the engagement of the device to be tested with the testing board 22. This engagement provides a ground plane contact. Further, and for example, the testing board 22 may include mounting points 82 for connection thereto of components for maintaining the position of a device on the testing board 22. For example, as shown in FIGS. 6 and 7, alignment members 84 may be secured to the mounting points 82 to maintain the position of a device 86 (e.g., ferrite circulator or isolator) on the testing board 22. The connection of the alignment members 84 to the mounting points 82 may be provided using fasteners, such as screws 88. Additionally, the alignment members 84 may include any component or member configured to maintain the position and/or alignment of the device 86 relative to the testing board 22 and/or testing interfaces 24, such as, alignment blocks, alignment plates, alignment pins, alignment posts, etc.

Thus, in operation, a device to be tested with the testing fixture 20 may be mounted and/or secured to the testing board 22. The testing interfaces 24 are configured to accommodate variances in the height at different connection points of the device using the resilient grounding members 42 and the flexible extension 78. In particular, compensation is provided for variations in the relative planar position of, for example, RF connecting tabs and the ground plane of the device to be tested. Accordingly, the testing fixture 20 accommodates planar tolerances between the grounding plane and the RF signal contact pins/leads that may be present, for example, in a rigid lead of a ferrite device.

While the invention has been described in terms of various specific embodiments, those skilled in the art will recognize that the invention can be practiced with modification within the spirit and scope of the claims.

what is claimed is:

1. A test fixture comprising:
a testing board configured to receive a surface mount device; and
at least one testing interface configured to connect the testing board with the surface mount device and configured to compensate for planar deviations of the connection between the surface mount device and the at least one testing interface.

2. A test fixture in accordance with claim 1 further comprising a resilient grounding member, the at least one testing interface engaging a top of the resilient grounding member.

3. A test fixture in accordance with claim 2 wherein the resilient grounding member is configured to allow vertical movement of the at least one testing interface relative to the testing board.

4. A test fixture in accordance with claim 1 wherein the at least one testing interface comprises an interface portion and a based portion flexibly connected together.

5. A test fixture in accordance with claim 4 further comprising a flexible extension extending from the interface portion and configured to connect to a connection strip of the base portion allowing upward and downward movement of the base portion relative to the interface portion.

6. A test fixture in accordance with claim 4 further comprising a gap between the base portion and the interface portion.

7. A test fixture in accordance with claim 1 wherein the at least one testing interface extends above a top surface the testing board.

8. A test fixture in accordance with claim 1 further comprising a gap between the at least one testing interface and the testing board.

9. A test fixture in accordance with claim 1 further comprising a mounting portion configured to receive therein at least a portion of the surface mount device.

10. A test fixture in accordance with claim 9 further comprising a vacuum port in combination with the mounting portion.

11. A test fixture in accordance with claim 1 further comprising mounting points configured to mount alignment members to the testing board.

12. A test fixture in accordance with claim 1 wherein the surface mount device comprises at least one of a surface mount ferrite isolator and a surface mount ferrite circulator.

13. A test fixture in accordance with claim 1 further comprising at least one recessed portion configured to receive therein a portion of the at least one testing interface.

14. A test fixture in accordance with claim 13 further comprising at least another recessed portion below the at least one recessed portion and configured to receive therein a resilient grounding member.

15. A test fixture in accordance with claim 1 wherein the at least one testing interface is configured to move in a z-direction and resist movement in both an x-direction and a y-direction.

16. A surface mount device test fixture comprising:
a testing board configured to support a ferrite type surface mount device;
a plurality of testing interfaces configured to connect the ferrite type surface mount device to a ground plane of the testing board, the plurality of testing interfaces configured to move perpendicularly relative to the testing board; and
a resilient grounding member supporting each of the plurality of testing interfaces.

17. A surface mount device test fixture in accordance with claim 16 wherein each of the plurality of testing interfaces comprises a base portion and an interface portion flexibly connected to the base portion to allow the perpendicular movement.

18. A surface mount device test fixture in accordance with claim 16 wherein the resilient grounding member comprises a foam rubber material, at least a portion of the resilient grounding member surrounded by a conductive layer.

19. A surface mount device test fixture in accordance with claim 16 wherein the plurality of testing interfaces extend above the ground plane of the testing board.

20. A method for testing a surface mount device, the method comprising:
configuring a testing board to receive a surface mount device; and
movingly engaging at least one testing interface with the testing board, the at least one testing interface configured to connect the surface mount device to the testing board.
